(19) United States
(12) Patent Application Publication
(10) Pub. No.: US 2003/0127190 A1
(43) Pub. Date: Jul. 10, 2003

(54) CHANNEL SLEEVE, IMPROVED PLASMA PROCESSING CHAMBER CONTAINING CHANNEL SLEEVE, AND METHODS OF MAKING AND USING THE SAME

(76) Inventors: KENNETH G. FLUGAUR, SHAKOPEE, MN (US); MARTIN A. SCHLECHT, WOODBURY, MN (US)

Correspondence Address: CHRISTOPHER P. MAIORANA, P.C., 24025 GREATER MACK, SUITE 200, ST. CLAIR SHORES, MI, 48080, US

(21) Appl. No.: 09/460,638

(22) Filed: Dec. 14, 1999

Related U.S. Application Data
(60) Provisional application No. 60/114,181, filed on Dec. 30, 1998.

(51) Int. Cl. H01L 21/306; C23C 16/00

(52) U.S. Cl. 156/345.33; 156/345.1; 118/715

(57) ABSTRACT

A device comprising an outer portion comprising an electrically insulative material, having dimensions effective to prevent or inhibit plasma arcing to an electrically conductive surface of a plasma processing chamber aperture and an inner opening, completely surrounded by the electrically insulative material of the outer portion, having dimensions effective to enable transmission of a physical signal or a gas, gas mixture or other material through the device.

This application claims the benefit of U.S. Provisional Application No. 60/114,181, filed Dec. 30, 1998 and is hereby incorporated by reference in its entirety.

### FIELD OF THE INVENTION

The present invention relates to a novel channel sleeve, an improved plasma processing chamber containing the channel sleeve, an improved method of making plasma processing chamber and improved plasma processing methods using the improved plasma processing chamber generally and, more particularly, to a particular advantage in plasma etching and/or deposition processes, particularly for processing a semiconductor and/or integrated circuit.

### BACKGROUND OF THE INVENTION

Conventional plasma processing apparatuses contain a plurality of apertures (alternatively, channels, vias, ports, inlets and/or outlets) for transmitting optical and/or electrical information and/or for transferring gases and/or other materials into or out of the chamber. For example, one may spectroscopically examine the chamber atmosphere/environment to obtain chemical, electrical and/or processing information, from which other information and/or data may be derived, such as whether or not the plasma has been ignited, the percentage of a particular component of the plasma, the completeness of the process (e.g., an “endpoint” detection/determination), etc. However, problems may arise when an electrically conductive material is exposed in such an aperture. For example, a secondary plasma may form outside the containment boundaries of the original/primary plasma and arc to an aperture having an exposed electrically conductive material. Such secondary plasmas not only damage the devices/apertures/chambers, but also increase the number of particles formed in the chamber during the process.

In one illustrative example, particles comprising aluminum and fluorine are formed when the aperture has exposed aluminum and the plasma comprises a fluorine-containing species, such as CHF₃, CF₄, C₂F₆, C₂H₂F₄, SF₆, etc. Even when the aperture comprises a channel having exposed anodized aluminum, the secondary plasma may break through the anodization, resulting in sputtering the underlying aluminum and formation of additional particles (although the number of particles correlates to the age of the chamber in this case). In the semiconductor/integrated circuit manufacturing industry, such particles degrade the electrical and/or physical properties of the semiconductor/integrated circuit products and/or reduce the yield of the manufacturing process. In addition, when the plasma comprises carbon-containing species (such as CHF₃, CF₄, C₂F₆, C₂H₂F₄, c—C₄F₈, etc.), polymers may form and build up in/on the walls of the aperture. Such polymers may adversely affect apertures for transmission or removal of gases or optical signals.

One approach to preventing such secondary plasmas is to insert a sapphire plug into the aperture. However, such sapphire plugs adversely affect spectroscopic examinations of the plasma. For example, conventional sapphire plugs completely (or partially) attenuate (block) spectroscopic endpoint determination signals in one conventional plasma etching apparatus. Such a decrease in intensity can make the signal unusable in certain applications. Also, as a practical matter, conventional sapphire plugs tend to be harder than conventional insulator ceramics, and may damage ceramic insulator materials in an aperture. Once damaged, the aperture may not hold the plug as securely, leading to an increased possibility for the above-identified problems. Additionally, if the sapphire plug is held in place by a lip on the ceramic ring, the lip can be easily damaged during cleaning and during installation of the sapphire plug. Such a damaged lip can cause problems due to the jagged/broken ceramic lip.

### SUMMARY OF THE INVENTION

The present invention concerns the present channel sleeve overcomes the problems of conventional plasma chamber technology by blocking the arc path to electrically conductive surfaces of chamber apertures, while at the same time, not blocking the signal or material transmission path(s) of the aperture. Thus, in one embodiment, the present invention concerns a device comprising:

an outer portion comprising an electrically insulative material, having dimensions effective to prevent or inhibit plasma arcing to an electrically conductive surface of a plasma processing chamber aperture, and

an inner opening, completely surrounded by the electrically insulative material of the outer portion, having dimensions effective to enable transmission of a physical signal or a gas, gas mixture or other material through the device.

In a further embodiment, the present invention concerns a plasma processing chamber comprising:

at least one aperture therein, the at least one aperture having an exposed electrically conductive surface, and

a device fitting inside the aperture, the device comprising an electrically insulative material and having (i) dimensions effective to prevent or inhibit plasma arcing to the exposed electrically conductive surface of the aperture, and (ii) an inner opening completely surrounded by the electrically insulative material, the inner opening having dimensions effective to enable transmission of a physical signal or a gas, gas mixture or other material through the device.

In a further embodiment, the present invention concerns a method of making a plasma processing chamber, the chamber having at least one aperture therein, the at least one aperture having an exposed electrically conductive surface, the method comprising:

inserting a device into the aperture, the device comprising an electrically insulative material and having (i) dimensions effective to prevent or inhibit plasma arcing to the exposed electrically conductive surface of the aperture, and (ii) an inner opening completely surrounded by the electrically insulative material, the inner opening having dimensions effective to enable transmission of a physical signal or a gas, gas mixture or other material through the device.

In a further embodiment, the present invention concerns a method of processing a workpiece, comprising:

(A) exposing the workpiece to a plasma in a chamber, the chamber having at least one aperture therein, the at least one aperture having (i) an exposed electrically conductive surface, and (ii) a device in the aperture, the device comprising an electrically insulative material and having (a) dimensions effective to prevent or inhibit plasma arcing to the exposed electrically conductive surface of the aperture, and (b) an inner opening completely surrounded by the electrically insulative material, the inner opening having dimensions effective to enable transmission of a physical signal or a gas, gas mixture or other material through the device; and

(B) transmitting a physical signal or a gas, gas mixture or other material through the device into or out from the chamber.

### BRIEF DESCRIPTION OF THE DRAWINGS

These and other objects, features and advantages of the present invention will be apparent from the following detailed description and the appended claims and drawings in which:

FIG. 1 is a diagram of a channel sleeve in accordance with a preferred embodiment of the present invention; and

FIGS. 2a and 2b illustrate side and top view of the aperture of FIG. 1.

### DETAILED DESCRIPTION OF THE PREFERRED EMBODIMENTS

As described above, the present device (hereinafter, “channel sleeve”) may comprise an outer portion (e.g., the “sleeve”) with an opening or aperture therein. The present channel sleeve may be made completely or partially from an electrically insulative material. If partially made from an electrically insulative material, at least the surface(s) of the channel sleeve exposed after insertion into a plasma chamber aperture (e.g., the inner, top and bottom surfaces, as well as any outer surfaces not completely contained within or otherwise in contact with the chamber aperture) essentially comprise an electrically insulative substance.

Suitable electrically insulative substances include, but are not limited to, ceramics, such as silica or metal silicate(s) (which may be conventionally doped with one or more substances such as boron and/or phosphorous), alumina or metal aluminate (s) (which may be similarly doped), metal aluminosilicate(s) (which may also be conventionally doped), other multi-crystal ceramic materials, etc.; insulative polymers, such as polyvinyl polymers (e.g., polytetrafluoroethylene [e.g., TEFLON]), polyethylene, polypropylene, polyimides (e.g., VESPEL, available commercially from Du Pont, Wilmington, Del.), polycarbonates (e.g., LEXAN, available commercially from GE Plastics, Pittsfield, Mass.), etc.; and single crystal insulative minerals, such as sapphire, garnet, diamond, etc.

Preferably, the electrically insulative substance is selected from the group consisting of multi-crystal ceramics, polytetrafluoroethylene, polyimides, and polycarbonates. Most preferred electrically insulative substances include multi-crystal ceramics, which tend to physically, chemically and/or electrically match insulators (e.g., an insulator ring between chambers in a plasma etching apparatus) typically present in plasma processing chamber hardware. Single crystal insulative minerals are less preferred due to the potential for chamber aperture damage (and cost), and polytetrafluoroethylene is less preferred due to its potential breakdown/decomposition in or near a plasma.

When the electrically insulative substance comprises an Insulative polymer, the channel sleeve may further comprise an aperture compression or fitting device to provide an effective amount of pressure against the aperture wall to hold the channel sleeve in place in the aperture under predetermined and/or typical conditions of plasma processing. The aperture compression or fitting device may comprise, for example, a wire loop (which may be open or closed), having an outer circumference, diameter or length either the same as or slightly greater than that of the corresponding dimension(s) of the aperture. The outer circumference, diameter or length of the wire loop may be no more than 10%, preferably 5%, more preferably 1%, greater than the corresponding dimension(s) of the aperture.

The dimensions of the channel sleeve should be effective to prevent or inhibit plasma arcing to an electrically conductive surface of a plasma processing chamber aperture. Preferably, the dimensions of the channel sleeve are also effective to fit in the plasma processing chamber aperture within one or more predefined tolerances. For example, the predefined tolerance for a given dimension (which may apply to length, width, height, or thickness) may be ±0.02 inch, preferably ±0.01 inch, more preferably ±0.005 inch, and most preferably ±0.001 inch. Alternatively, the predefined tolerance for a given dimension may be from ±0.005% to ±0.5%, preferably from about ±0.02% to about ±0.1%. For a given angle, the predefined tolerance may be ±2°, preferably ±1°. Alternatively, the predefined tolerance for a given angle may be ±5%, preferably from about ±2% to about ±3%.

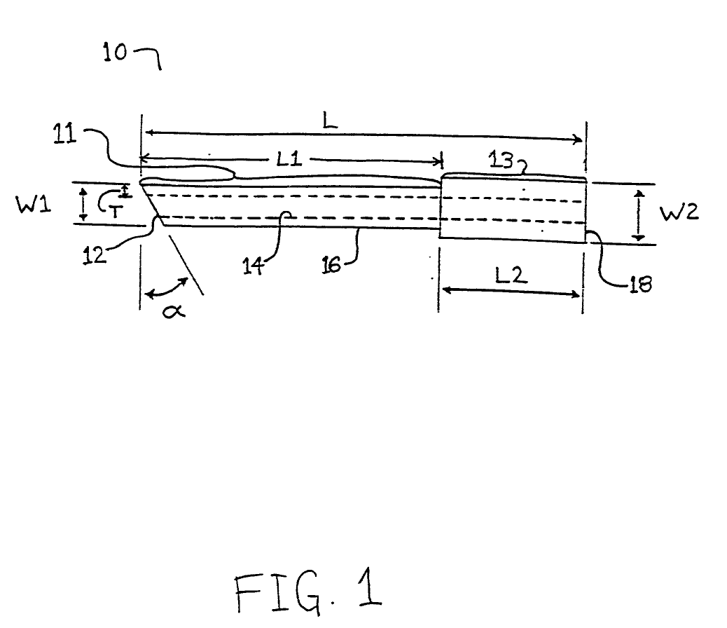

With reference to FIG. 1, the present channel sleeve 10 may have a length L, a width W, thickness T, a top 18, a bottom 12, an inner surface 14 and an outer surface 16. When viewed from the top or bottom, the shape of the chamber aperture may be round/cylindrical, square, rectangular, triangular, hexagonal, etc. The shape(s) of the top and bottom may be independent from one another.

In a preferred embodiment, the channel sleeve 10 may have two sections along the length L, a lower section 11 to fit inside the chamber aperture, and a higher section 13 to remain outside the aperture. The width(s) W1 of the lower section 11 is/are generally about the same as the corresponding chamber aperture width. The width(s) W2 of the higher section 13 is/are generally larger than the corresponding chamber aperture width.

In another embodiment, the bottom 12 of the channel sleeve 10 may have a non-orthogonal angle α with reference to the length of the channel sleeve. A non-orthogonal angle to the channel sleeve bottom 12 may ease insertion of the channel sleeve 10 into the aperture. However, a channel sleeve bottom 12 with an orthogonal angle may be easier to fabricate.

The channel sleeve 10 may have an inner opening, completely surrounded by the electrically insulative material, having dimensions effective to enable transmission of a physical signal or a gas, gas mixture or other material through the device. The width and/or thickness (defined by either or both of the two smallest orthogonal dimensions) or diameter (if the sleeve has a round or cylindrical shape) of the opening may define the thickness of the sleeve or sleeve sections.

More specific examples of suitable dimensions and angles follow:

| Dimension | Smallest | Largest | Actual Examples |
|---|---|---|---|
| Overall | 0.375 in. | 10.000 in. | 2.715 in., 4.208 in. |
| Length | | | |
| L1 | 0.250 in. | 7.500 in. | 1.215 in., 2.440 in. |
| L2 | 0.125 in. | 2.500 in. | 0.768 in., 1.500 in. |
| Overall | 0.063 in. | 1.500 in. | |
| Width | | | |
| W1 | 0.063 in. | 1.000 in. | 0.370 in., 0.375 in. |
| W2 | 0.100 in. | 1.500 in. | 0.500 in., 0.570 in. |
| Opening | 0.031 in. | 0.750 in. | 0.250 in. |
| Bottom | 30° | 90° | 58°, 90° |
| Angle | | | |

In a further embodiment, the present invention concerns an improved plasma processing chamber that has the present channel sleeve in an aperture. Except for the channel sleeve, the plasma processing chamber is otherwise conventional. Consequently, the aperture may be located in a wall, barrier or other structure in the chamber. The wall or barrier may be internal (i.e., contained completely within) or external (i.e., defining the barrier between the chamber and the external environment).

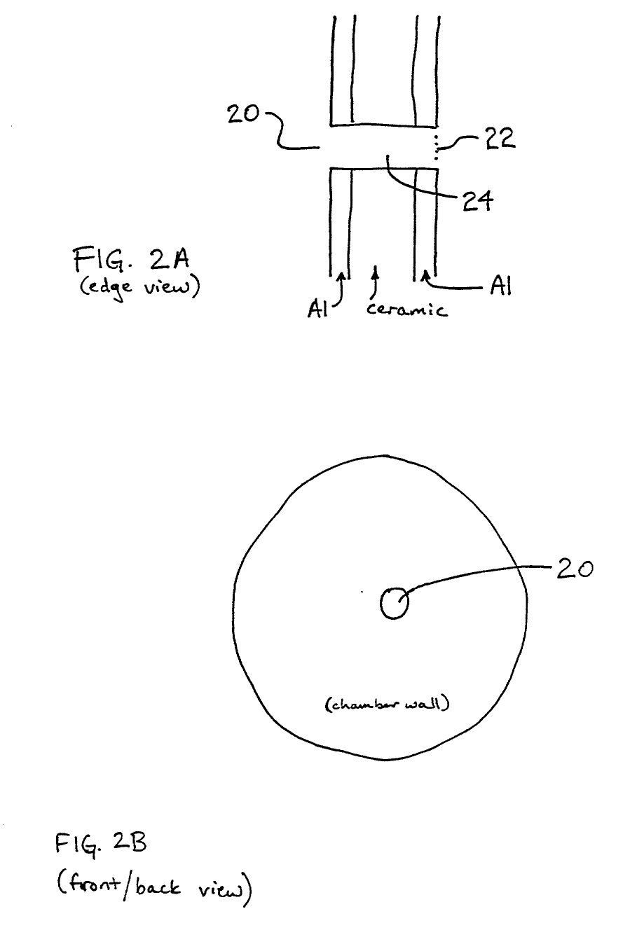

The plasma processing chamber has at least one aperture therein, and may have a plurality of apertures therein. At least one of the apertures has an exposed electrically conductive surface that may provide a kind of electrode with which a secondary plasma may interact. With respect to FIG. 2, the aperture 20 may comprise a chamber interface section 22 and a channel section 24. The chamber interface section 22 may be defined by the surface plane(s) of the chamber structure containing the aperture 20. When the chamber interface section 22 comprises an exposed electrically conductive surface, a corner and/or edge thereof may provide a particularly attractive potential electrode for a secondary plasma. The channel section 24 may be defined by an interior surface of the chamber structure through which the aperture conducts one or more material(s) or signal(s). The channel section 24 may provide the bulk of the particle-forming material. The chamber interface section 22 and the channel section 24 may independently have a surface that wholly or partially comprises an exposed electrically conductive material.

Typical electrically conductive materials include aluminum, titanium, iron, chromium, and alloys thereof. Most typically, the electrically conductive material comprises aluminum and/or a conventional alloy thereof.

The aperture is generally located outside the plasma containment area(s) of the chamber. Thus, the chamber may further comprise one or more plasma containment structures.

In a further embodiment, the present invention concerns a method of making a plasma processing chamber, the chamber having at least one aperture therein, and the aperture having an exposed electrically conductive surface. The method generally comprises inserting the present channel sleeve into the aperture. However, this method may further comprise the step of forming at least one aperture in the chamber prior to inserting the channel sleeve into the aperture.

As described above, the channel sleeve is typically designed to fit securely into the aperture. Thus, the dimensions of the channel sleeve generally match the dimensions of the aperture, preferably within the tolerances described above.

In a further embodiment, the present invention concerns a method of processing a workpiece, comprising:

exposing the workpiece to a plasma in a chamber, the chamber having:

at least one aperture therein, the at least one aperture having an exposed electrically conductive surface, and

a device in the aperture, the device comprising an electrically insulative material and having:

dimensions effective to prevent or inhibit plasma arcing to the exposed electrically conductive surface of the aperture, and

an inner opening completely surrounded by the electrically insulative material, the inner opening having dimensions effective to enable transmission of a physical signal or a gas, gas mixture or other material through the device; and

transmitting a physical signal or a gas, gas mixture or other material through the device into or out from the chamber.

In this method, the workpiece may comprise a semiconductor, an integrated circuit, or a partially-constructed or formed semiconductor or integrated circuit. Preferably, the workpiece comprises a semiconductor substrate, an insulator layer thereon, and a conductive layer thereon (which may be over, under and/or alongside the insulator layer). Optionally, the workpiece may further comprise an etch stop layer (which may be located below the insulator and/or conductive layer[s] but above the semiconductor substrate, preferably between the insulator and conductive layers) and/or one or more photoresist layers located over the uppermost layer.

In method of processing a workpiece, the processing step(s) may include a plasma etch process and/or a plasma deposition process, preferably a plasma etch process, and more preferably a plasma-enhanced self-aligned contact etch process that selectively etches one or more insulator layer(s) (preferably an insulator layer comprising a silicon oxide) over a conductive layer and/or a different insulator layer (e.g., a layer comprising polysilicon or a silicon nitride).

The present invention may further concern a method of operating a plasma processing chamber, wherein the chamber has at least one aperture therein, the aperture has an exposed electrically conductive surface, and the present channel sleeve is in the aperture. This method generally comprises initiating, striking or creating a plasma in the chamber (preferably for a predetermined period of time), then cleaning the chamber and channel sleeve. Preferably, this method further comprises, either between the initiating and cleaning steps or after the cleaning step (preferably after the cleaning step), the steps of removing the channel sleeve from the aperture and further cleaning the channel sleeve. Optionally, one may inspect the channel sleeve before and/or after the further cleaning step.

The chamber and channel sleeve may be cleaned by conventional wet or dry cleaning methods, but preferably, by a method comprising at least one conventional wet cleaning step. Such wet cleaning may involve immersing in and/or rinsing with an organic solvent (to remove polymers deposited during plasma processing) and/or with a conventional inorganic cleaning solvent (e.g., a dilute aqueous solution of acidic [e.g., aq. HCl] or basic [e.g., aq. ammonia or ammonium hydroxide] hydrogen peroxide [e.g., SC-1]) to remove metal or mineral contaminants. The chamber may also be cleaned by a conventional dry cleaning process comprising generating a plasma in an atmosphere containing oxygen (O₂) or a source of oxygen (e.g., O₃, N₂O, etc.) and a sulfur fluoride (e.g., SF₆) in the chamber.

Optionally, the channel sleeve may be dried, preferably by heating in an oven or furnace to a temperature up to, e.g., 400° C. (up to about 120° C. if the channel sleeve comprises an electrically insulative polymer), or by passing dry, filtered gas (e.g., nitrogen, air, argon, helium, etc.), which may be optionally heated to a temperature up to, e.g., 400° C. (preferably between 40° C. and 120° C.), over the channel sleeve.

The method of operating a plasma processing chamber may further comprise, between the initiating and cleaning steps, the method of processing a workpiece described above.

In its various embodiments, the present channel sleeve effectively prevents (or at least significantly inhibits) formation and/or generation of secondary plasmas in plasma processing chamber apertures/channels. In turn, this resulted in reduced defect counts during processing of workpieces in plasma processing chamber having the channel sleeve in at least one aperture.

In actual practice, the present channel sleeve, fabricated from a conventional ceramic material and having the dimensions of the actual examples listed in the table above (e.g., tolerances=±0.001 inch), was inserted into the endpoint detection channels of the upper chambers of nine (9) conventional, commercially available plasma etching apparatuses (including Lam 9500 plasma etch systems, obtained from Lam Research Corporation, Fremont, Calif.). A series of semiconductor wafers were subjected to a plasma-enhanced self-aligned contact etching process in each of the plasma etching apparatuses. Defect counts for ≧0.25 mm particles were consistently about or below 0.1 defects/cm². No attenuation of the spectroscopic endpoint detection signal strength was encountered.

The present invention further saves wear-and-tear on the plasma processing equipment, thereby reducing and/or eliminating at least one cause for replacing chamber hardware, increasing plasma processing equipment uptime and saving considerable amounts of money.

While the invention has been particularly shown and described with reference to the preferred embodiments thereof, it will be understood by those skilled in the art that various changes in form and details may be made without departing from the spirit and scope of the invention.

1. A device comprising:
an outer portion comprising an electrically insulative material, having dimensions effective to prevent or inhibit plasma arcing to an electrically conductive surface of a plasma processing chamber aperture, and
an inner opening, completely surrounded by the electrically insulative material of the outer portion, having dimensions effective to enable transmission of a physical signal or a gas, gas mixture or other material through the device.

2. A plasma processing chamber having:
at least one aperture therein, the at least one aperture having an exposed electrically conductive surface, and
the device of claim 1, located inside the aperture.

3. A method of making a plasma processing chamber, the chamber having at least one aperture therein, the at least one aperture having an exposed electrically conductive surface, the method comprising inserting the device of claim 1 into the aperture.

4. A method of processing a workpiece, comprising the following steps:
(A) exposing the workpiece to a plasma in the chamber of claim 2; and
(B) transmitting a physical signal or a gas, gas mixture or other material through the device into or out from the chamber.

5. A plasma processing chamber having:
at least one aperture therein, the at least one aperture having an exposed electrically conductive surface, and
a device inside the aperture, the device comprising an electrically insulative material and having
(i) dimensions effective to prevent or inhibit plasma arcing to the exposed electrically conductive surface of the aperture; and
(ii) an inner opening completely surrounded by the electrically insulative material, the inner opening having dimensions effective to enable transmission of a physical signal or a gas, gas mixture or other material through the device.

6. A method of making a plasma processing chamber, the chamber having at least one aperture therein, the at least one aperture having an exposed electrically conductive surface, the method comprising inserting a device into the aperture, the device comprising an electrically insulative material and having:
dimensions effective to prevent or inhibit plasma arcing to the exposed electrically conductive surface of the aperture, and
an inner opening completely surrounded by the electrically insulative material, the inner opening having dimensions effective to enable transmission of a physical signal or a gas, gas mixture or other material through the device.

7. The method of claim 6, further comprising, prior to said inserting, the step of forming said aperture in said chamber.

8. A method of processing a workpiece, comprising:
exposing the workpiece to a plasma in a chamber, the chamber having at least one aperture therein, the at least one aperture having
1) an exposed electrically conductive surface; and
2) a device in the aperture, the device comprising an electrically insulative material and having
(i) dimensions effective to prevent or inhibit plasma arcing to the exposed electrically conductive surface of the aperture; and
(ii) an inner opening completely surrounded by the electrically insulative material, the inner opening having dimensions effective to enable transmission of a physical signal or a gas, gas mixture or other material through the device; and
(iii) transmitting a physical signal or a gas, gas mixture or other material through the device into or out from the chamber.

9. A method of operating a plasma processing chamber, wherein the chamber has at least one aperture therein and the aperture has an exposed electrically conductive surface, the method comprising the steps of:
(A) initiating a plasma in the chamber, the aperture having the device of claim 1 therein, then
(B) cleaning the chamber and the device.

10. The method of claim 9, wherein said plasma exists in said chamber for a predetermined period of time.

11. The method of claim 9, further comprising, prior to said inserting, the steps of:
exposing a workpiece to the plasma, and transmitting a physical signal or a gas, gas mixture or other material through the device into or out from the chamber.
